(19) United States
(12) Patent Application Publication
(10) Pub. No.: US 2011/0308594 A1
(43) Pub. Date: Dec. 22, 2011

(54) SOLAR CELL HAVING IMPROVED LIGHT-TRAPPING STRUCTURE

(75) Inventors: Shih-Shou Lo, Hsinchu County (TW); Der-Jun Jan, Taoyuan County (TW); Dison Huang, Kaohsiung County (TW)

(73) Assignee: Institute of Nuclear Energy Research Atomic Energy Council, Executive Yuan, Taoyuan County (TW)

(21) Appl. No.: 12/905,737

(22) Filed: Oct. 15, 2010

(30) Foreign Application Priority Data
Jun. 22, 2010 (TW) 099120264

(51) Int. Cl. H01L 31/0232

(52) U.S. Cl. 136/256

(57) ABSTRACT

The present invention provides a solar cell, which has an improved light-trapping structure, wherein the light trapping structure is a single layer of thin film made of a plurality of zinc oxide microballs whose diameter is ranged between 300 nm and 650 nm. In a preferred embodiment, the light trapping layer, being configured with a plurality of microballs made of zinc oxide, is disposed at a position between the front surface of a photovoltaic conversion layer and a front electrode of the solar cell. Since the light-trapping structure is formed directly from the ZnO transparent conductive layer of the solar cell, the types of materials used for constructing the solar cell are reduced.

### CROSS-REFERENCE TO RELATED APPLICATION

This non-provisional application claims priority under 35 U.S.C. §119(a) on Patent Application No(s). 099120264 filed in Taiwan, R.O.C. on Jun. 22, 2010, the entire contents of which are hereby incorporated by reference.

### FIELD OF THE INVENTION

The present invention relates to a solar cell, and more particularly, to a solar cell having light-trapping structure made of zinc oxide (ZnO).

### BACKGROUND OF THE INVENTION

As more and more scientists all over the world had agreed that the natural greenhouse effect is enhanced by greenhouse gasses emitted in mass quantities since the birth of the Industrial Revolution and is continuing to escalade over time and eventually will alter the Earth's core temperature enough to completely change the Earth as we know it, referring as the global warming crisis. Therefore, in order to reduce the generation of manmade greenhouse gases, more and more green energy technologies had been developed and among which solar power is considered to be one of the most promising renewable energy sources in the world. Since there will be no greenhouse gases, such as carbon dioxide, being generated during the process of using solar cells for converting the energy of sunlight directly into electricity by the photovoltaic effect, it is possible to greatly relieve the global warming crisis if the solar cells are widely used all over the world. The best way for making solar cells to become more popular is to improve the solar cell's efficiency without causing any increment in its manufacturing cost and complexity, which is becoming the focus point in the solar cell development.

With poor efficiency, only a small fraction of the sunlight radiating upon a conventional solar cell is absorbed and converted into electricity since more of the sunlight is reflected from the incident surface of the solar cell. Thus, it is noted that the solar cell's efficiency can be greatly improved if such reflection can be greatly reduced. Accordingly, there are many light-trapping techniques being developed. One of which is achieved by texturing the incident surface of silicon solar cells, in that the textured surface is formed on the incident surface of a solar cell by a lithography process, a dry-etching process, or a wet-etching process. However, the forming of the textured surface by the lithography process is disadvantageous in that: not only the equipment for the lithography process can be very expensive, but also the performing of the lithography process can be very time-consuming and costly. Nevertheless, if it is formed by dry- or wet-etching process, it is difficult to maintain uniform in composition during each etching process, and thus, in mass production, the reliability as well as the quality of the solar cell can not be ensured.

### SUMMARY OF THE INVENTION

The object of the invention is to provide a solar cell, especially a solar cell whose front electrode is a transparent conductive layer made of zinc oxide, having an improved light-trapping structure, being a single layer of thin film made of a plurality of zinc oxide microballs with diameters ranged between 300 nm and 650 nm. Since the light-trapping structure is formed directly from the ZnO transparent conductive layer of the solar cell, the types of materials used for constructing the solar cell are reduced.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a schematic diagram showing a solar cell according to a first embodiment of the present invention.

FIG. 2 is a schematic diagram showing a solar cell according to a second embodiment of the present invention.

FIG. 3 is a schematic diagram showing a solar cell manufacturing equipment of the present invention.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

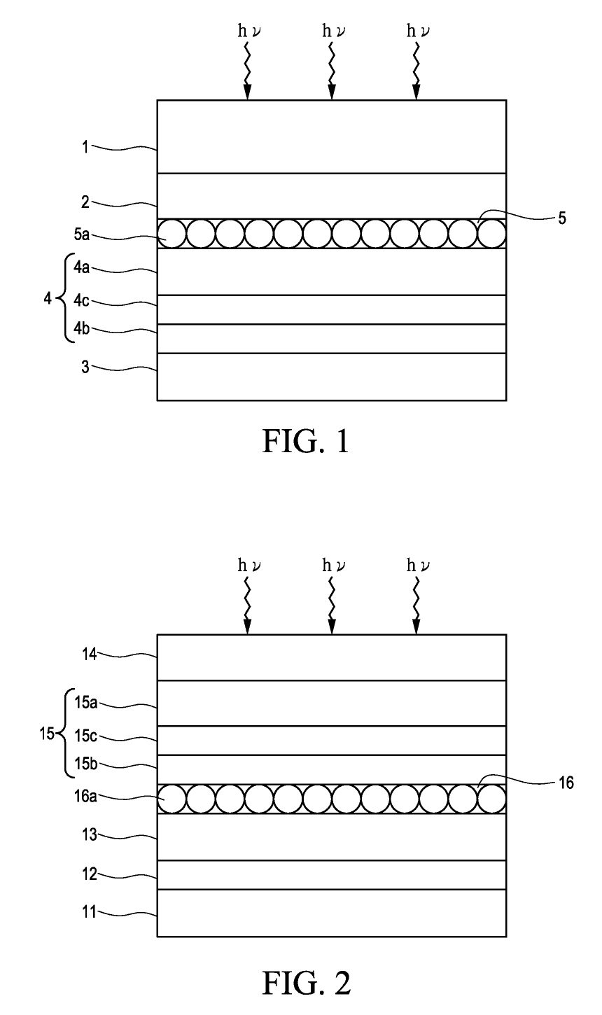

The present invention relates to a solar cell, especially to a solar cell having an improved light-trapping structure mad of ZnO. Please refer to FIG. 1 which is a schematic diagram showing a solar cell according to a first embodiment of the present invention. As shown in FIG. 1, the solar cell comprises:
a glass substrate 1;
a front electrode 2;
a back electrode 3, disposed at a position for enabling the front electrode 2 to be arranged between the glass substrate 1 and the back electrode 3;
a photovoltaic conversion layer 4, formed with a front surface and a back surface and disposed at a position between the front electrode 2 and the back electrode 3 while enabling electromagnetic waves to incident thereto through the front surface so as to be used for absorbing the electromagnetic waves and thus generating hole-electron pairs while transporting the holes to the front electrode 2 (the arrows indicated as hv that are shown in FIG. 1 and FIG. 2 represent the incident directions of the electromagnetic wave); and
a light trapping layer 5, having a plurality of microballs 5a made of zinc oxide and disposed at a position between the front surface of the photovoltaic conversion layer 4 and the front electrode 2.

It is noted that the front electrode 2 can be a finger electrode that the material as well as the manufacturing method of such finger electrode had already been provided in many researches and thus will not be described further herein. In addition, the front electrode 2 can be made of a transparent conductive oxide, such as zinc oxide (ZnO). Consequently, the plural microballs 5a used in the present invention for forming the light trapping layer 5 can be made of ZnO, and thus the types of materials used for constructing the solar cell can be reduced.

In this embodiment, the back electrode 3 can be made of a metal, such as aluminum, or a transparent conductive oxide, such as zinc oxide (ZnO). Similarly, the material as well as the manufacturing method of the back electrode 3 had already been provided in many researches and thus will not be described further herein.

Moreover, in this embodiment, the photovoltaic conversion layer 4 can be a p-n semiconductor junction composed of a p-type semiconductor layer 4a and an n-type semiconductor layer 4b. Preferably, the photovoltaic conversion layer 4 can be formed as an intrinsic semiconductor layer 4c sandwiched between the p-type semiconductor layer 4a and the n-type semiconductor layer 4b, by that the thickness of the layer in the solar cell used for absorbing sunlight is increased. In addition, all of the intrinsic semiconductor layer 4c, the p-type semiconductor layer 4a and the n-type semiconductor layer 4b are semiconductor layers containing silicon. It is noted that the material as well as the manufacturing method of the photovoltaic conversion layer 4 had already been provided in many researches and thus will not be described further herein.

In this embodiment, the plural ZnO microballs 5a is being constructed into a single layer of ZnO microball structure so as to be used as the light trapping layer 5. Preferably, the diameter of each of the microball 5a is ranged between 300 nm and 650 nm, by that a two-dimensional grating can be formed with respect to the electromagnetic waves whose wavelengths are ranged between 700 nm to 1200 nm. It is noted that each of the plural microballs 5a can be a solid sphere or a hollow sphere.

In addition, by a process of spraying, CVD or PVD, the light trapping layer 5 that is substantially a single layer of ZnO microball structure is being embedded inside a layer of ZnO thin film whereas the thin film can be made of intrinsic ZnO, n-type ZnO, or p-type ZnO. Thereby, the whole structure is substantially be constructed as a layer of ZnO thin film having a single layer of ZnO microball structure embedded therein; and since the refraction index of the ZnO thin film is different from that of the single layer of ZnO microball structure, the whole structure is able to trap the light in a manner that a beam entering the aforesaid structure will be reflect and refract multiple times therein before exiting the same.

Please refer to FIG. 2, which is a schematic diagram showing a solar cell according to a second embodiment of the present invention. As shown in FIG. 1, the solar cell comprises:
a stainless steel substrate 11;
a back electrode 13;
a front electrode 14, disposed at a position for enabling the back electrode 13 to be arranged between the stainless steel substrate 11 and the front electrode 14;
an insulation layer 12, disposed at a position between the stainless steel substrate 11 and the back electrode 13 of insulating the stainless steel substrate 11 from the back electrode 13;
a photovoltaic conversion layer 15, formed with a front surface and a back surface and disposed at a position between the front electrode 14 and the back electrode 13 while enabling electromagnetic waves to incident thereto through the front surface and those electromagnetic waves that are not being absorbed to be projected out of the same from the back surface so as to be used for absorbing the electromagnetic waves and thus generating hole-electron pairs while transporting the holes to the front electrode 14; and
a light trapping layer 16, having a plurality of microballs 16a made of zinc oxide and disposed at a position between the back surface of the photovoltaic conversion layer 15 and the back electrode 13.

It is noted that the front electrode 14 can be a finger electrode that the material as well as the manufacturing method of such finger electrode had already been provided in many researches and thus will not be described further herein. In addition, the front electrode 14 can be made of a transparent conductive oxide, such as zinc oxide (ZnO). Consequently, the plural microballs 16a used in the present invention for forming the light trapping layer 16 can be made of ZnO, and thus the types of materials used for constructing the solar cell can be reduced. In this embodiment, the back electrode 13 can be made of a metal, such as aluminum. Similarly, the material as well as the manufacturing method of the back electrode 13 had already been provided in many researches and thus will not be described further herein.

In addition, in this embodiment, the insulation layer 12 is used for insulating the stainless steel substrate 11 from the back electrode 13, so that it can be made of SiO₂ for instance. Similarly, the material as well as the manufacturing method of the insulation layer 12 had already been provided in many researches and thus will not be described further herein.

Moreover, in this embodiment, the photovoltaic conversion layer 15 can be a p-n semiconductor junction composed of a p-type semiconductor layer 15a and an n-type semiconductor layer 15b. Preferably, the photovoltaic conversion layer 15 can be formed as an intrinsic semiconductor layer 15c sandwiched between the p-type semiconductor layer 15a and the n-type semiconductor layer 15b, by that the thickness of the layer in the solar cell used for absorbing sunlight is increased. In addition, all of the intrinsic semiconductor layer 15c, the p-type semiconductor layer 15a and the n-type semiconductor layer 15b are semiconductor layers containing silicon. It is noted that the material as well as the manufacturing method of the photovoltaic conversion layer 15 had already been provided in many researches and thus will not be described further herein.

Similarly, the plural ZnO microballs 16a is being constructed into a single layer of ZnO microball structure so as to be used as the light trapping layer 16. Preferably, the diameter of each of the microball 5a is ranged between 300 nm and 650 nm, by that a two-dimensional grating can be formed with respect to the electromagnetic waves whose wavelengths are ranged between 700 nm to 1200 nm. It is noted that each of the plural microballs 16a can be a solid sphere or a hollow sphere.

In addition, by a process of spraying, CVD or PVD, the light trapping layer 5 that is substantially a single layer of ZnO microball structure is being embedded inside a layer of ZnO thin film whereas the thin film can be made of intrinsic ZnO, n-type ZnO, or p-type ZnO. Thereby, the whole structure is substantially be constructed as a layer of ZnO thin film having a single layer of ZnO microball structure embedded therein;

and since the refraction index of the ZnO thin film is different from that of the single layer of ZnO microball structure, the whole structure is able to trap the light in a manner that a beam entering the aforesaid structure will be reflect and refract multiple times therein before exiting the same.

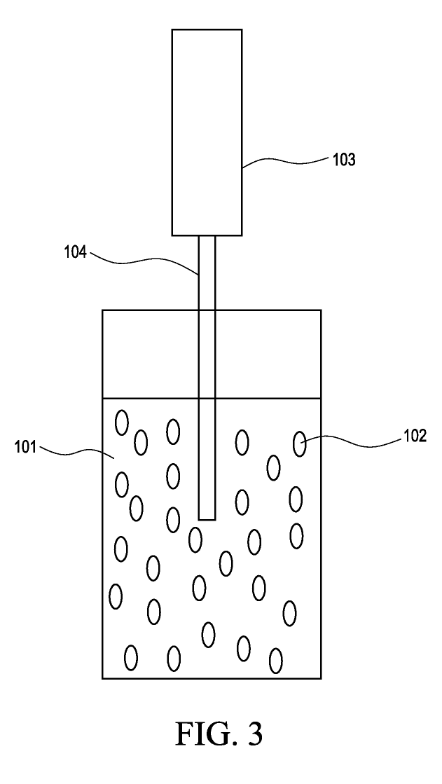

Please refer to FIG. 3, which is a schematic diagram showing a solar cell manufacturing equipment of the present invention. As shown in FIG. 3, the solar cell manufacturing equipment is substantially an immersion coating system with working temperature ranged between 20° C. to 70° C. The immersion coating system is configured with a coating tank 101 for holding a tank of coating liquid therein, whereas the coating liquid is a volatile solvent having a plurality of ZnO microballs 102 floating and uniformly distributed therein. It is noted that the volatile solvent can be made of a pure alcohol, or the compositions of more than one type of alcohol at different ratios, such as ethanol, ethylene glycol or diethylene glycol, etc.; and the weight percentage of the ZnO microballs 102 in the volatile solvent is ranged between 5% to 25%. As shown in FIG. 3, during the manufacturing of a solar cell of the present invention, the substrate 104 of the solar cell is clamped and hold by a clamping apparatus 103 for submerging the substrate 104 into the coating liquid in the coating tank 101, and during which the speed of the substrate 104 being submerged into the coating liquid as well as that being pulling of the coating liquid are adjusted according to the volume and the concentration of the volatile solvent for depositing and forming the single layer of ZnO microball structure on the substrate 104. In this embodiment, the aforesaid speed can be ranged between 0.03 cm/min and 3 cm/min. It is noted that if the substrate 104 is a glass substrate 1 as the one shown in FIG. 1, it should already be configured with a front electrode at a surface thereof; and if the substrate 104 is a stainless steel substrate 11 as the one shown in FIG. 2, it should already be configured with an insulation layer 12 and a back electrode 13 on a surface thereof while enabling the insulation layer 12 to be sandwiched between the surface of the substrate 11 and the back electrode 13.

Operationally, in one embodiment of the invention, a 50 mm×50 mm glass substrate 104 of 2 mm in thickness that is fixedly secured and hold by the clamping apparatus 103 of the immersion coating system is being placed and submerged into a volatile solvent consisting of ZnO microball with a weight percentage of 10%. According to the speed of the clamping apparatus 103 for submerging and pulling the substrate 104 into and out of the volatile solvent that is controlled by a computer, there will be a single layer of ZnO microball structure being uniformly deposited and formed on the substrate 104.

To sum up, the present invention has the following advantages:
(1) As the front electrode is made of ZnO and the light trapping structure is also made of ZnO microballs, the types of materials used for constructing the solar cell can be reduced.
(2) As the manufacturing equipment for the solar cell of the invention is an immersion coating system, substrates of the solar cells can be process under a low-temperature environment without being affected by factors such as the thickness, shape and conductivity of the substrate, so that not only it can be used for processing a large-sized substrate, but also it enables the mass production of the solar cell with respect to the processing of the substrate to be possible, since the manufacturing using the aforesaid equipment is easy to performed and also can overcome the disadvantage of the lithography process for processing large-sized substrates.
(3) By enabling each of the microball to be formed with a diameter ranged between 300 nm and 650 nm and thus forming a two-dimensional grating specifically designed for the electromagnetic waves whose wavelengths are ranged between 700 nm to 1200 nm, the manufacturing accuracy can be controlled and ensured.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A solar cell, comprising:
a glass substrate;
a front electrode;
a back electrode, disposed at a position for enabling the front electrode to be arranged between the glass substrate and the back electrode;
a photovoltaic conversion layer, formed with a front surface and a back surface and disposed at a position between the front electrode and the back electrode while enabling electromagnetic waves to incident thereto through the front surface so as to be used for absorbing the electromagnetic waves and thus generating hole-electron pairs while transporting the holes to the front electrode; and
a light trapping layer, having a plurality of microballs made of zinc oxide and disposed at a position between the front surface of the photovoltaic conversion layer and the front electrode.

2. The solar cell of claim 1, wherein the front electrode is made of zinc oxide.

3. The solar cell of claim 1, wherein the photovoltaic conversion layer further comprises: a p-type semiconductor layer and an n-type semiconductor layer.

4. The solar cell of claim 3, wherein the photovoltaic conversion layer further comprises:
an intrinsic semiconductor layer, sandwiched between the p-type semiconductor layer and the n-type semiconductor layer.

5. The solar cell of claim 4, wherein all of the intrinsic semiconductor layer, the p-type semiconductor layer and the n-type semiconductor layer are semiconductor layers containing silicon.

6. The solar cell of claim 1, wherein a single layer of ZnO microball structure is formed from the composition of the plural ZnO microballs.

7. The solar cell of claim 6, wherein the diameter of each of the plural ZnO microballs is ranged between 300 nm and 650 nm.

8. A solar cell, comprising:
a stainless steel substrate;
a back electrode;
a front electrode, disposed at a position for enabling the back electrode to be arranged between the stainless steel substrate and the front electrode;
an insulation layer, disposed at a position between the stainless steel substrate and the back electrode of insulating the stainless steel substrate from the back electrode;
a photovoltaic conversion layer, formed with a front surface and a back surface and disposed at a position between the front electrode and the back electrode while enabling electromagnetic waves to incident thereto through the front surface and those electromagnetic waves that are not being absorbed to be projected out of the same from the back surface so as to be used for absorbing the electromagnetic waves and thus generating hole-electron pairs while transporting the holes to the front electrode; and
a light trapping layer, having a plurality of microballs made of zinc oxide and disposed at a position between the back surface of the photovoltaic conversion layer and the back electrode.

9. The solar cell of claim 8, wherein the front electrode is made of zinc oxide.

10. The solar cell of claim 8, wherein the photovoltaic conversion layer further comprises: a p-type semiconductor layer and an n-type semiconductor layer.

11. The solar cell of claim 10, wherein the photovoltaic conversion layer further comprises:
an intrinsic semiconductor layer, sandwiched between the p-type semiconductor layer and the n-type semiconductor layer.

12. The solar cell of claim 11, wherein all of the intrinsic semiconductor layer, the p-type semiconductor layer and the n-type semiconductor layer are semiconductor layers containing silicon.

13. The solar cell of claim 8, wherein a single layer of ZnO microball structure is formed from the composition of the plural ZnO microballs.

14. The solar cell of claim 13, wherein the diameter of each of the plural ZnO microballs is ranged between 300 nm and 650 nm.
